(19) United States
(12) Patent Application Publication
(10) Pub. No.: US 2025/0107419 A1
(43) Pub. Date: Mar. 27, 2025

(54) METHOD OF MANUFACTURING DISPLAY DEVICE

(71) Applicant: Samsung Display Co., LTD., Yongin-si (KR)

(72) Inventors: KYUNG-MAN KIM, Yongin-si (KR); SUNGHOON KIM, Yongin-si (KR)

(73) Assignee: Samsung Display Co., LTD., Yongin-si (KR)

(21) Appl. No.: 18/763,372

(22) Filed: Jul. 3, 2024

(30) Foreign Application Priority Data
Sep. 22, 2023 (KR) 10-2023-0127509

(51) Int. Cl. H10K 59/80; H10K 59/12

(52) U.S. Cl. CPC H10K 59/8793; H10K 59/1201; H10K 59/8722

(57) ABSTRACT

A method of manufacturing a display device includes forming a light emitting element layer on a mother substrate, forming a through portion in a dummy area of a preliminary encapsulation substrate to form at least one bridge connecting a cell area of the preliminary encapsulation substrate and the dummy area adjacent to the cell area, bonding the mother substrate and the preliminary encapsulation substrate, applying a sealing member through the through portion, the sealing member extending from an upper surface of the mother substrate to a side surface of the preliminary encapsulation substrate which is exposed by the through portion, and cutting the at least one bridge and separating the dummy area of the preliminary encapsulation substrate.

### CROSS-REFERENCE TO RELATED APPLICATION

This application claims priority and benefits of Korean Patent Application No. 10-2023-0127509 under 35 USC § 119, filed in the Korean Intellectual Property Office on Sep. 22, 2023, the entire contents of which are incorporated herein by reference.

### BACKGROUND

### 1. Technical Field

The disclosure relates to a method of manufacturing a display device with improved process reliability.

### 2. Description of the Related Art

The importance of display devices as communication medium has been emphasized because of the increasing developments of information technology. Also, users of display devices such as liquid crystal display (LCD) device, organic light emitting display (OLED) device, plasma display panel (PDP) device, quantum dot display device or the like have been increasing and becoming more popular.

A head mounted display (HMD) includes a display device. The HMD is a device worn like glasses or a helmet which includes screens for eyes. The HMDs are used in virtual reality (VR) or augmented reality (AR) and project content at a close distance to the user's eyes. The HMD uses lenses to provide images generated by the display device to the user's eyes. The HMD may include a high-resolution micro organic light emitting diode (OLED). The high-resolution micro OLED may be an OLEDOS (organic light emitting diode on silicon) formed using a silicon wafer-based semiconductor process.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a method of manufacturing a display device preventing defects caused by fine glass fragments generated during physical processing of an encapsulation substrate.

A method of manufacturing a display device according to an embodiment of the disclosure includes forming a light emitting element layer on a mother substrate, forming a through portion in a dummy area of a preliminary encapsulation substrate to form at least one bridge connecting a cell area of the preliminary encapsulation substrate and the dummy area adjacent to the cell area, bonding the mother substrate and the preliminary encapsulation substrate, applying a sealing member through the through portion, the sealing member extending from an upper surface of the mother substrate to a side surface of the preliminary encapsulation substrate which is exposed by the through portion, and cutting the at least one bridge and separating the dummy area of the preliminary encapsulation substrate.

In an embodiment, the cutting of the at least one bridge may include applying an impact to an outer side surface of the preliminary encapsulation substrate.

In an embodiment, the applying of the impact to the outer side surface of the preliminary encapsulation substrate may include applying the impact in a second direction perpendicular to a first direction in which the at least one bridge extends.

In an embodiment, the applying of the impact to the outer side surface of the preliminary encapsulation substrate may include applying the impact in a diagonal direction between a first direction in which the at least one bridge extends and a second direction perpendicular to the first direction.

In an embodiment, a width of a central portion of the at least one bridge may be smaller than a width of each end of the at least one bridge.

In an embodiment, a thickness of the at least one bridge may be smaller than a thickness of the preliminary encapsulation substrate.

In an embodiment, the forming of the through portion in the dummy area may include processing the side surface of the preliminary encapsulation substrate to have a chamfered shape. The side surface of the preliminary encapsulation substrate may overlap the cell area and is exposed by the through portion.

In an embodiment, the method may further include strengthening the preliminary encapsulation substrate through an ion exchange process between the forming of the through portion in the dummy area and the cutting of the at least one bridge.

In an embodiment, the mother substrate may be formed of a silicon wafer.

A method of manufacturing a display device according to another embodiment of the disclosure includes forming a light emitting element layer on a mother substrate, forming a through portion in a dummy area of a preliminary encapsulation substrate to form at least one bridge connecting a cell area of the preliminary encapsulation substrate and the dummy area adjacent to the cell area, forming a polarization layer on the preliminary encapsulation substrate, bonding the mother substrate and the preliminary encapsulation substrate, and cutting the at least one bridge and separating the dummy area of the preliminary encapsulation substrate.

In an embodiment, the forming of the polarization layer may include forming a preliminary polarization layer overlapping the cell area and the dummy area on the preliminary encapsulation substrate, and cutting the preliminary polarization layer and forming the polarization layer overlapping the cell area.

In an embodiment, the cutting of the preliminary polarization layer may include irradiating a laser to the preliminary polarization layer, and the irradiation of the laser may overlap both ends of the at least one bridge.

In an embodiment, the cutting of the preliminary polarization layer may include simultaneously cutting the preliminary polarization layer and the at least one bridge using the laser.

In an embodiment, the cutting of the preliminary polarization layer may be performed before the cutting of the at least one bridge.

In an embodiment, the cutting of the at least one bridge may include applying an impact to an outer side surface of the preliminary encapsulation substrate.

In an embodiment, the applying of the impact to the outer side surface of the preliminary encapsulation substrate may include applying the impact in a second direction perpendicular to a first direction in which the at least one bridge extends.

In an embodiment, the applying of the impact to the outer side surface of the preliminary encapsulation substrate may include applying the impact in a diagonal direction between a first direction in which the at least one bridge extends and a second direction perpendicular to the first direction.

In an embodiment, a width of a central portion of the at least one bridge may be smaller than a width of each end of the at least one bridge.

In an embodiment, the forming of the through portion in the dummy area may include processing a side surface of the preliminary encapsulation substrate to have a chamfered shape, and the side surface of the preliminary encapsulation substrate may overlap the cell area and is exposed by the through portion.

In an embodiment, the method may further include strengthening the preliminary encapsulation substrate through an ion exchange process between the forming of the through portion in the dummy area and the cutting of the at least one bridge.

A method of manufacturing a display device according to embodiments of the disclosure may include processing a preliminary encapsulation substrate, which includes a cell area and a dummy area adjacent to the cell area, forming at least one bridge connecting the cell area and the dummy area, bonding a mother substrate and the preliminary encapsulation substrate, and cutting the at least one bridge and separating the dummy area of the preliminary encapsulation substrate.

For example, the method of manufacturing the display device includes the cutting of the at least one bridge and the separating of the dummy area of the preliminary encapsulation substrate. Thus, the dummy area of the preliminary encapsulation substrate may be separated from the mother substrate without a physical processing method using a diamond wheel or a dicing saw. Accordingly, a problem caused by fine-sized fragments of the preliminary encapsulation substrate, which may be generated during the physical processing method, remaining on an encapsulation substrate may be prevented.

### BRIEF DESCRIPTION OF THE DRAWINGS

An additional appreciation according to the embodiments of the disclosure will become more apparent by describing in detail the elements thereof with reference to the accompanying drawings, wherein:

FIG. 1 is a schematic plan view illustrating a display device according to an embodiment of the disclosure;

FIG. 2 is a schematic enlarged plan view of area ‘A’ of FIG. 1;

FIG. 3 is a schematic cross-sectional view taken along line II-II′ of FIG. 2; FIG. 4 is a schematic cross-sectional view taken along line I-I′ of FIG. 1;

FIG. 5 is a schematic flowchart of a method of manufacturing a display device according to an embodiment of the disclosure;

FIGS. 6 to 20 are schematic views illustrating the method of manufacturing the display device of FIG. 5;

FIG. 21 is a schematic flowchart of a method of manufacturing a display device according to another embodiment of the disclosure; and

FIGS. 22 to 32 are schematic views illustrating the method of manufacturing the display device of FIG. 21.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

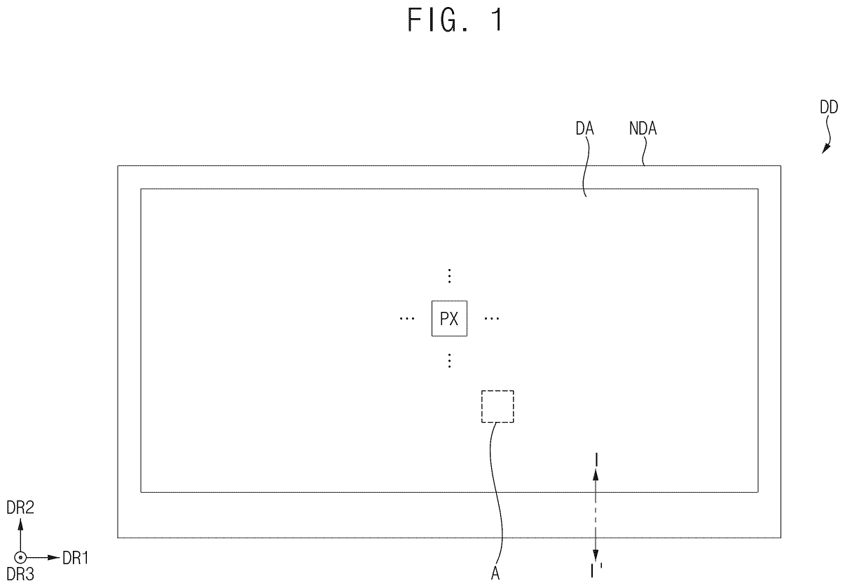

FIG. 1 is a schematic plan view illustrating a display device according to an embodiment of the disclosure.

In this specification, a plane may be defined by a first direction DR1 and a second direction DR2 intersecting (e.g., crossing) the first direction DR1. For example, the first direction DR1 and the second direction DR2 may be perpendicular to each other. A direction normal to the plane may be a third direction DR3. For example, the third direction DR3 may be a thickness direction of a display device DD. For example, the third direction DR3 may be perpendicular to each of the first direction DR1 and the second direction DR2.

Referring to FIG. 1, the display device DD according to an embodiment of the disclosure may include a display area DA and a non-display area NDA.

An image may be displayed in a display area DA. The display area DA may have a rectangular planar shape. However, the planar shape of the display area DA is not limited thereto, and the display area DA may have various planar shapes such as a circular shape, an oval shape, a polygonal shape, or the like.

Images may not be displayed in the non-display area NDA. The non-display area NDA may be adjacent to (e.g., be positioned around) the display area DA. For example, the non-display area NDA may entirely surround the display area DA. Drivers for displaying an image in the display area DA may be disposed in the non-display area NDA.

Pixels PX for generating an image may be disposed in the display area DA. The pixels PX may emit lights, and the lights emitted from the pixels PX may be combined to generate the image. For example, the pixels PX may be disposed in a matrix shape in the first direction DR1 and the second direction DR2.

Signal lines such as gate lines and data lines may be disposed in the display area DA. Each of the pixels PX may be electrically connected to the signal lines. Each of the pixels PX may receive a gate signal, a data signal, etc. from the signal lines. Accordingly, an image may be displayed in the display area DA in the third direction DR3.

The display device DD according to an embodiment of the disclosure may be various display devices that display images. For example, the display device may be an organic light emitting display device, a liquid crystal display device, an organic light emitting diode on silicon substrate (OLEDos), a liquid crystal on silicon substrate (LCos), a light emitting diode on silicon substrate (LEDos), or the like.

In an embodiment, the display device DD may be an organic light emitting diode on silicon substrate (OLEDos). In case that the display device DD is the OLEDos, the display device DD may configure a head-mounted display (HMD). The HMD may be a glasses-type monitor device for virtual reality or augmented reality. The HMD may be worn in the form of glasses, a helmet, etc. In the HMD, a focal point may be formed on a close distance in front of the user's eyes. However, embodiments of the disclosure are not limited thereto, and the display device DD may configure various displays.

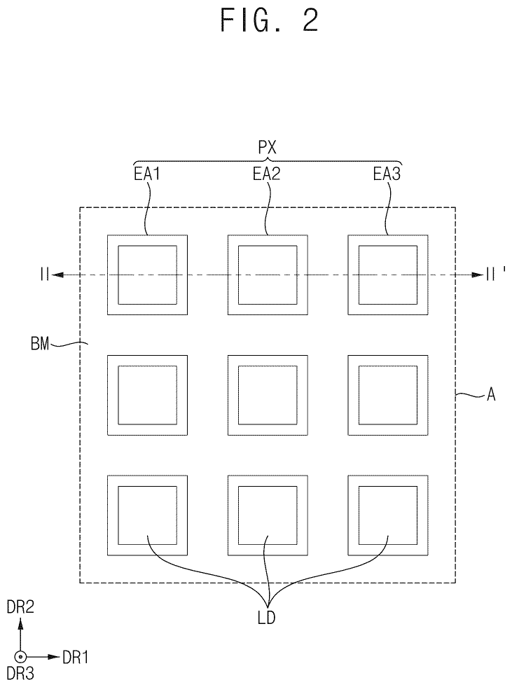

FIG. 2 is a schematic enlarged plan view of area ‘A’ of FIG. 1.

Referring to FIG. 2, each of the pixels PX may include a first light emitting area EA1, a second light emitting area EA2, and a third light emitting area EA3 that emit light. In FIG. 2, each of the pixels PX may include three light emitting areas EA1, EA2, and EA3. However, the disclosure is not limited thereto, and each of the pixels PX may include four or more light emitting areas.

For example, each of the first light emitting area EA1, the second light emitting area EA2, and the third light emitting area EA3 may have a triangular planar shape, a square planar shape, a circular planar shape, a track-shaped planar shape, an ellipse planar shape, etc. In an embodiment, each of the first light emitting area EA1, the second light emitting area EA2, and the third light emitting area EA3 may have a rectangular planar shape. However, the disclosure is not limited thereto, and each of the first light emitting area EA1, the second light emitting area EA2, and the third light emitting area EA3 may have various planar shapes. For example, one of the first light emitting area EA1, the second light emitting area EA2, and the third light emitting area EA3 may have a size and/or a shape different from one or more of the first light emitting area EA1, the second light emitting area EA2, and the third light emitting area EA3. In other embodiments, the first light emitting area EA1, the second light emitting area EA2, and the third light emitting area EA3 may have a same size and/or a same shape.

Each of the first light emitting area EA1, the second light emitting area EA2, and the third light emitting area EA3 may include a light emitting element LD that emits a first light. For example, the first light may be white light. However, the disclosure is not limited thereto, and the light emitting element LD included (or disposed) in the first light emitting area EA1 may emit red light, the light emitting element LD included in the second light emitting area EA2 may emit green light, and the light emitting element LD included in the third light emitting area EA3 may emit blue light.

The first light emitting area EA1 may emit a second light. The first light emitting area EA1 may convert the first light emitted from the light emitting element LD into the second light and emit the second light. For example, the second light may be red light, but the disclosure is not limited thereto.

The second light emitting area EA2 may emit a third light. The second light emitting area EA2 may convert the first light emitted from the light emitting element LD into the third light and emit the third light. For example, the third light may be green light, but the disclosure is not limited thereto.

The third light emitting area EA3 may emit a fourth light. The third light emitting area EA3 may convert the first light emitted from the light emitting element LD into the fourth light and emit the fourth light. For example, the fourth light may be blue light, but the disclosure is not limited thereto.

The first light emitting area EA1, the second light emitting area EA2, and the third light emitting area EA3 may be arranged in the first direction DR1. For example, the first light emitting area EA1, the second light emitting area EA2, and the third light emitting area EA3 may be disposed in an order of the first light emitting area EA1, the second light emitting area EA2, and the third light emitting area EA3 in the first direction DR1. For example, the second light emitting area EA2 may be disposed between the first light emitting area EA1 and the third light emitting area EA3 in the first direction DR1. The first light emitting area EA1, the second light emitting area EA2, and the third light emitting area EA3 may be arranged in the second direction DR2. However, the disclosure is not limited thereto.

The first light emitting area EA1, the second light emitting area EA2, and the third light emitting area EA3 may be defined by a light blocking portion (or a black matrix) BM. The light blocking portion BM may be adjacent to (e.g., surround) each of the first light emitting area EA1, the second light emitting area EA2, and the third light emitting area EA3. For example, the light blocking portion BM may be disposed between adjacent ones of the first light emitting area EA1, the second light emitting area EA2, and the third light emitting area EA3. For example, the light blocking portion BM may have a mesh shape, a net shape, a lattice shape, etc. in a plan view.

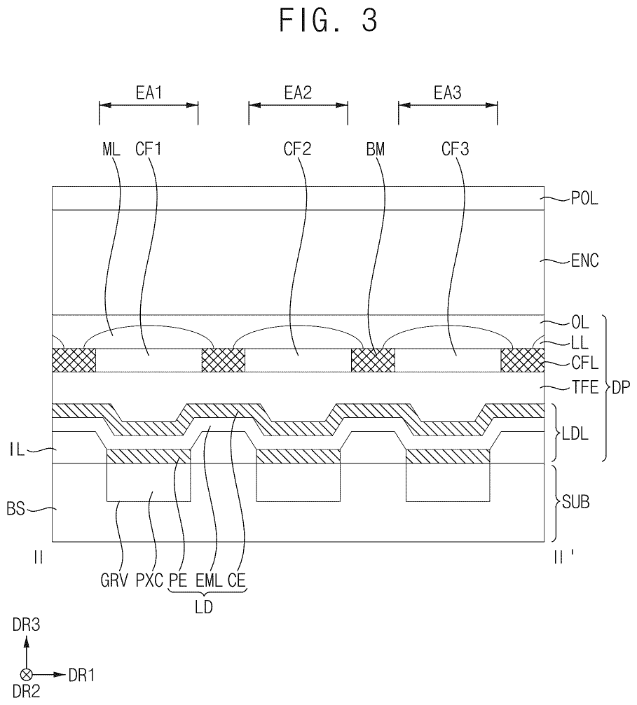

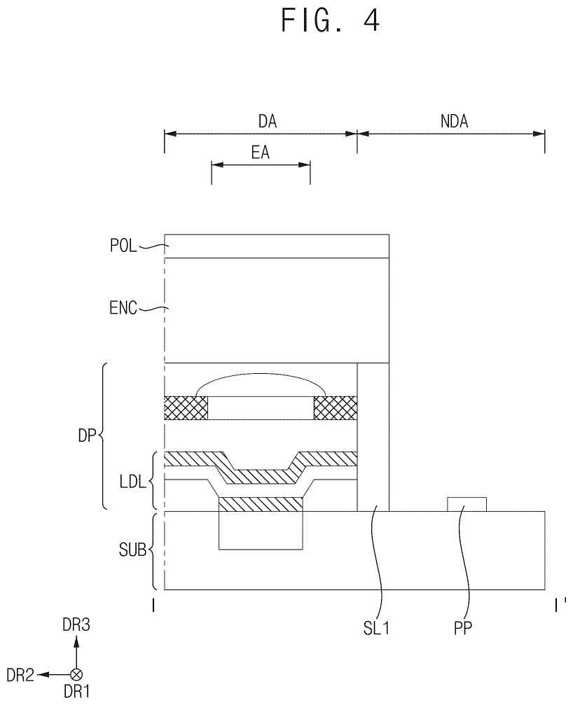

FIG. 3 is a schematic cross-sectional view taken along line II-II′ of FIG. 2.

Referring to FIGS. 1 and 3, the display device DD according to an embodiment of the disclosure may include a substrate SUB, a display layer DP, an encapsulation substrate ENC, and a polarization layer POL.

The substrate SUB may include a base substrate BS and pixel circuit portions PXC. In an embodiment, the substrate SUB may be a semiconductor circuit board. The substrate SUB may include a silicon wafer.

The base substrate BS may define grooves GRV. The pixel circuit portions PXC may be accommodated in (e.g., be disposed in) the grooves GRV, respectively. Each of the pixel circuit portions PXC may include at least one transistor. Each of the pixel circuit portions PXC may further include at least one capacitor.

The display layer DP may be disposed on the substrate SUB. The display layer DP may include a light emitting element layer LDL, an encapsulation layer TFE, a color filter layer CFL, a lens layer LL, and a filling layer (e.g., an overcoating layer) OL.

The light emitting element layer LDL may be disposed on the substrate SUB. The light emitting element layer LDL may include light emitting elements LD and an insulating layer IL. Each of the light emitting elements LD may include a pixel electrode PE, a light emitting layer EML, and a common electrode CE.

The insulating layer IL may be disposed on the substrate SUB. The insulating layer IL may define openings that expose the pixel circuit portions PXC. The insulating layer IL may include an inorganic insulating material and/or an organic insulating material. Examples of the inorganic insulating material that may be used as the insulating layer IL may include silicon oxide (SiOₓ), silicon nitride (SiNₓ), silicon oxynitride (SiOₓN_{y}), etc. These may be used alone or in combination with each other. Examples of the organic insulating material that may be used as the insulating layer IL may include photoresist, polyacryl-based resin, polyimide-based resin, polyamide-based resin, siloxane-based resin, acryl-based resin, epoxy-based resin, etc. These may be used alone or in combination with each other.

The pixel electrode PE may be disposed on the pixel circuit portions PXC in each of the first to third light emitting areas EA1, EA2, and EA3. For example, the pixel electrode PE may be disposed within the opening defined by the insulating layer IL. The pixel electrode PE may be electrically connected to the pixel circuit portion PXC. Accordingly, the pixel electrode PE may receive a voltage from the pixel circuit portion PXC. The pixel electrode PE may include a metal, an alloy, a metal nitride, a conductive metal oxide, a transparent conductive material, etc. Examples of material that may be used as the pixel electrode PE may include silver (Ag), an alloy including silver, molybdenum (Mo), an alloy including molybdenum, aluminum (Al), an alloy including aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other. For example, the pixel electrode PE may serve as an anode electrode.

The light emitting layer EML may be disposed on the pixel electrode PE and the insulating layer IL. For example, the light emitting layer EML may be disposed on the pixel electrodes PE in the first to third light emitting areas EA1, EA2, and EA3 and the insulating layer IL. The light emitting layer EML may extend along the first to third light emitting areas EA1, EA2, and EA3. However, the disclosure is not limited thereto, and the light emitting layer EML may be independently disposed in each of the first to third light emitting areas EA1, EA2, and EA3. The light emitting layer EML may include an organic material that emits light of a color (e.g., a preset or selectable color). In an embodiment, the light emitting layer EML may include an organic light emitting material that emits white light.

The common electrode CE may be disposed on the light emitting layer EML. The common electrode CE may extend along the first to third light emitting areas EA1, EA2, and EA3. The common electrode CE may include a metal, an alloy, a metal nitride, a conductive metal oxide, a transparent conductive material, etc. These may be used alone or in combination with each other. For example, the common electrode CE may serve as a cathode electrode.

Accordingly, the light emitting elements LD including the pixel electrode PE, the light emitting layer EML, and the common electrode CE may be disposed on the substrate SUB.

The encapsulation layer TFE may be disposed on the light emitting element layer LDL. The encapsulation layer TFE may prevent impurities, moisture, etc. from penetrating into the light emitting element layer LDL from the outside. The encapsulation layer TFE may include at least one inorganic encapsulation layer and at least one organic encapsulation layer. The inorganic encapsulation layer and the organic encapsulation layer may be alternately stacked with each other. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a cured polymer such as polyacrylate.

The color filter layer CFL may be disposed on the encapsulation layer TFE. The color filter layer CFL may include the light blocking portion BM, a first color filter CF1, a second color filter CF2, and a third color filter CF3.

The light blocking portion BM may be disposed on the encapsulation layer TFE. The light blocking portion BM may partition the first light emitting area EA1, the second light emitting area EA2, and the third light emitting area EA3. For example, the light blocking portion BM may define openings that partition the first to third light emitting areas EA1, EA2, and EA3. Accordingly, the light blocking portion BM may not overlap the first to third light emitting areas EA1, EA2, and EA3. The light blocking portion BM may include an inorganic material and/or an organic material with black color. For example, the light blocking portion BM may include black pigment, black dye, carbon black, etc. These may be used alone or in combination with each other.

The first color filter CF1, the second color filter CF2, and the third color filter CF3 may be disposed within the openings defined by the light blocking portion BM, respectively.

The first color filter CF1 may be disposed on the encapsulation layer TFE in the first light emitting area EA1. The first color filter CF1 may transmit the second light among the first light emitted from the light emitting element layer LDL, and may absorb or block the third light and the fourth light. For example, the first color filter CF1 may transmit red light and may absorb or block green light and blue light. However, the disclosure is not limited thereto.

The second color filter CF2 may be disposed on the encapsulation layer TFE in the second light emitting area EA2. The second color filter CF2 may transmit the third light among the first light emitted from the light emitting element layer LDL, and may absorb or block the second light and the fourth light. For example, the second color filter CF2 may transmit green light and may absorb or block red light and blue light. However, the disclosure is not limited thereto.

The third color filter CF3 may be disposed on the encapsulation layer TFE in the third light emitting area EA3. The third color filter CF3 may transmit the fourth light among the first light emitted from the light emitting element layer LDL and may absorb or block the second light and the third light. For example, the third color filter CF3 may transmit blue light and may absorb or block red light and green light. However, the disclosure is not limited thereto.

The lens layer LL may be disposed on the color filter layer CFL. The lens layer LL may include micro lenses ML. The micro lenses ML may be disposed on the first to third color filters CF1, CF2, and CF3, respectively. The micro lenses ML may have a refractive index (e.g., a predetermined or selectable refractive index). The micro lenses ML may improve light extraction efficiency. For example, the micro lenses ML may guide the light emitted from the first to third color filters CF1, CF2, and CF3 in the third direction DR3.

The filling layer OL may be disposed on the lens layer LL. The filling layer OL may flatten an upper surface of the color filter layer CFL and an upper surface of the lens layer LL. The filling layer OL may include an inorganic insulating material and/or an organic insulating material. Examples of the inorganic insulating material that may be used as the filling layer OL may include silicon oxide (SiOₓ), silicon nitride (SiNₓ), silicon oxynitride (SiOₓN_{y}), etc. These may be used alone or in combination with each other. Examples of the organic insulating material that may be used as the filling layer OL may include acrylic polymer, imide polymer, amide polymer, fluorine polymer, aryl ether polymer, vinyl alcohol polymer, etc. These may be used alone or in combination with each other.

The encapsulation substrate ENC may be disposed on the filling layer OL. The encapsulation substrate ENC may cover and protect the display layer DP. The encapsulation substrate ENC may be attached to a surface (e.g., an upper surface) of the display layer DP through an adhesive member. The encapsulation substrate ENC may include a transparent material. For example, the encapsulation substrate ENC may include glass or plastic. However, the disclosure is not limited thereto, and an encapsulation film or layer may be formed on the display layer DP.

The polarization layer POL may be disposed on the encapsulation substrate ENC. The polarization layer POL may reduce external light reflection of the display device DD. In case that external light reflection is reduced, visibility of the display device DD may be improved. In other embodiments, the polarization layer POL may be omitted.

FIG. 4 is a schematic cross-sectional view taken along line I-I′ of FIG. 1.

Referring to FIGS. 1 and 4, the display device DD according to an embodiment of the disclosure may include the substrate SUB, the display layer DP, the encapsulation substrate ENC, a first sealing member SL1, the polarization layer POL, and a pad portion PP.

The first sealing member SL1 may be disposed on the substrate SUB in the non-display area NDA. The first sealing member SL1 may cover a side surface of the display layer DP. The first sealing member SL1 may include an inorganic material. For example, the first sealing member SL1 may be a glass frit. The glass frit may include a main material such as glass (e.g., glass raw materials), silicon oxide, etc. in a powder form. The first sealing member SL1 may be in a paste state including the silicon oxide, a laser or infrared absorber, an organic binder, a filler to reduce the coefficient of thermal expansion, and the like. In case that a laser is irradiated to the first sealing member SL1, the first sealing member SL1 may be melted and cured.

The encapsulation substrate ENC may be disposed on the display layer DP and the first sealing member SL1. The encapsulation substrate ENC may overlap the display area DA and the non-display area NDA. For example, the encapsulation substrate ENC may entirely overlap the display area DA and partially overlap the non-display area NDA.

The polarization layer POL may be disposed on the encapsulation substrate ENC. The polarization layer POL may overlap (e.g., entirely overlap) the encapsulation substrate ENC. The polarization layer POL may overlap the display area DA and the non-display area NDA. For example, the polarization layer POL may entirely overlap the display area DA and partially overlap the non-display area NDA.

The pad portion PP may be disposed in the non-display area NDA positioned on a side of the display area DA. For example, the pad portion PP may be disposed in the non-display area NDA positioned on a lower side of the substrate SUB. The pad portion PP may be electrically connected to a printed circuit board, etc. The pad portion PP may be spaced apart from the display layer DP.

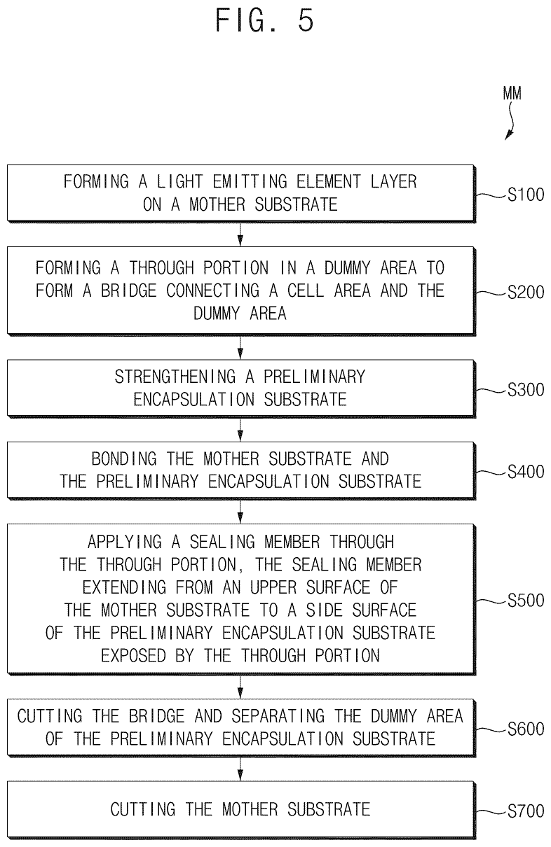

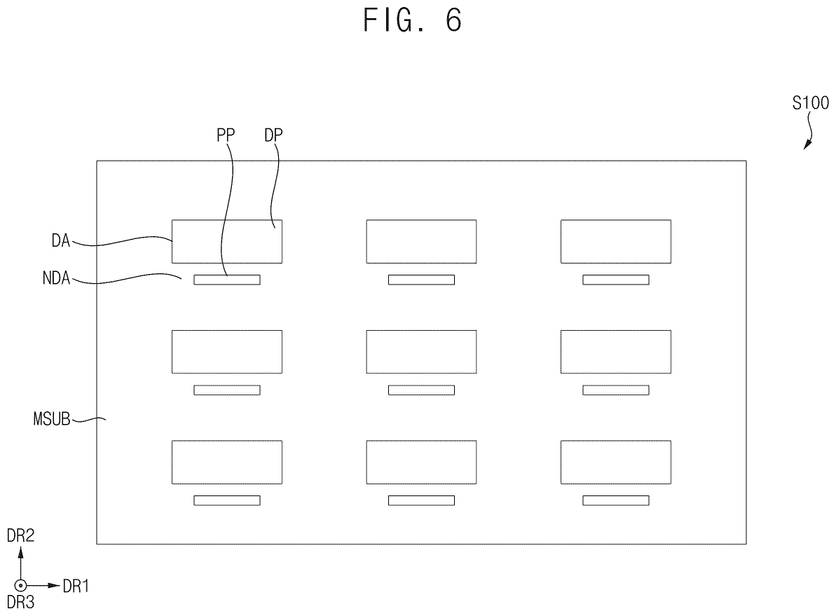

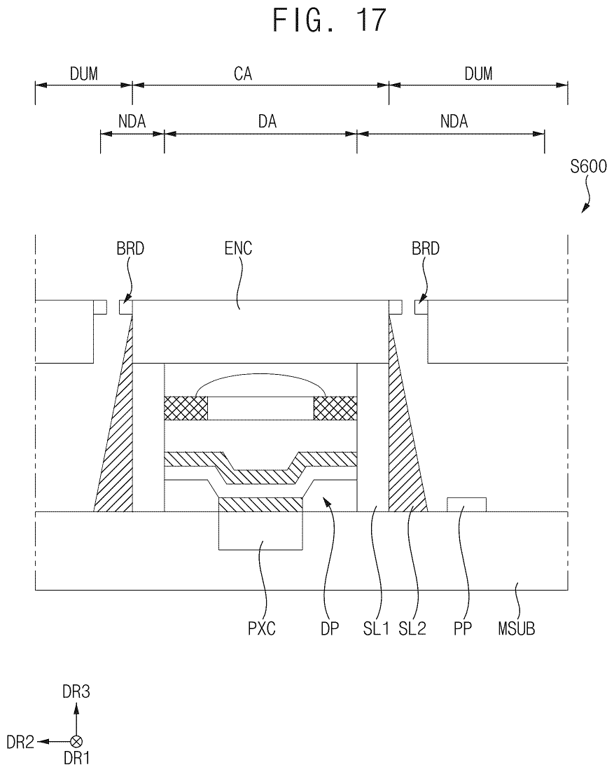

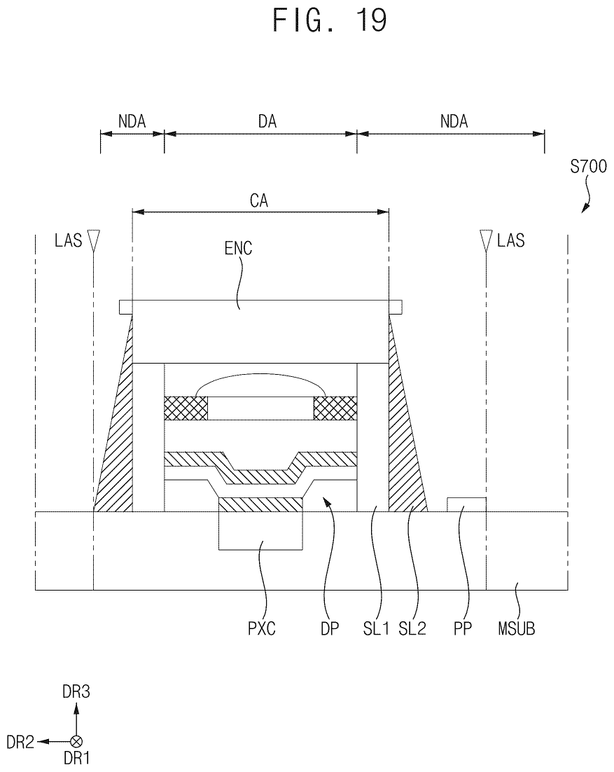

FIG. 5 is a schematic flowchart of a method of manufacturing a display device according to an embodiment of the disclosure. FIGS. 6 to 20 are schematic views illustrating the method of manufacturing the display device of FIG. 5.

Referring to FIG. 5, the method MM of manufacturing a display device according to an embodiment of the disclosure may include forming a light emitting element layer on a mother substrate (S100), forming a through portion in a dummy area to form a bridge connecting a cell area and the dummy area (e.g., processing a preliminary encapsulation substrate and forming the through portion in the dummy area to form the bridge connecting the cell area and the dummy area) (S200), strengthening the preliminary encapsulation substrate (S300), bonding the mother substrate and the preliminary encapsulation substrate (S400), applying (e.g., coating) a sealing member through the through portion, the sealing member extending from an upper surface of the mother substrate to a side surface of the preliminary encapsulation substrate exposed by the through portion (S500), cutting the bridge and separating the dummy area of the preliminary encapsulation substrate (S600), and cutting the mother substrate (S700). For example, the method MM of manufacturing the display device may include the forming of the light emitting element layer on the mother substrate (S100), the forming of the bridge connecting the cell area and the dummy area (S200), the strengthening of the preliminary encapsulation substrate (S300), the bonding of the mother substrate and the preliminary encapsulation substrate (S400), the applying of the sealing member through the through portion (S500), the separating of the dummy area of the preliminary encapsulation substrate (S600), and the cutting of the mother substrate (S700). The forming of the bridge connecting the cell area and the dummy area (S200) may include the processing of the preliminary encapsulation substrate and the forming of the through portion in the dummy area. In the applying of the sealing member through the through portion (S500), the sealing member may extend from the upper surface of the mother substrate to the side surface of the preliminary encapsulation substrate exposed by the through portion. The separating of the dummy area of the preliminary encapsulation substrate (S600) may include the cutting of the bridge.

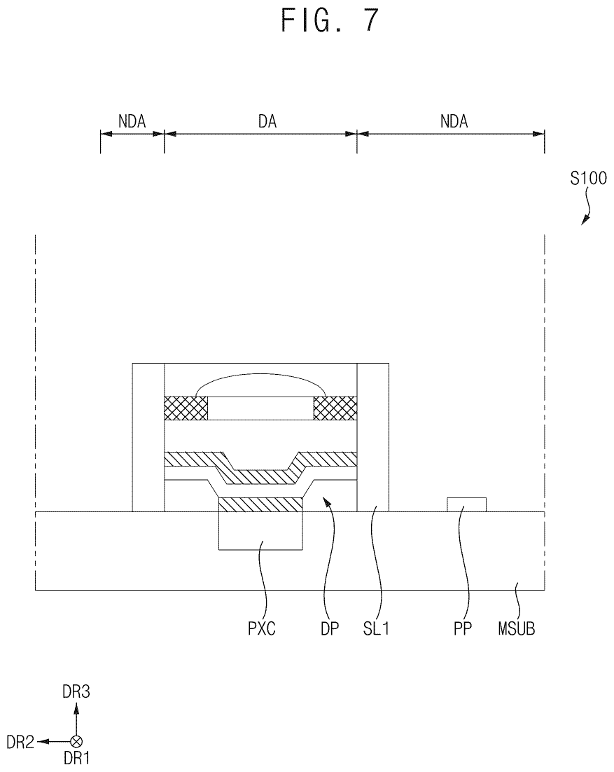

Referring to FIGS. 6 and 7, a light emitting element layer LDL (e.g., refer to FIG. 3) may be formed on a mother substrate MSUB (S100).

The mother substrate MSUB may be formed of a silicon wafer. The mother substrate MSUB may include substrates (e.g., the substrate SUB of FIG. 3). For example, the mother substrate MSUB may be cut, and the substrates may be formed. Pixel circuit portions PXC may be formed on the mother substrate MSUB.

Display layers DP, first sealing members SL1, and pad portions PP may be formed on the mother substrate MSUB.

The display layers DP may be formed in each display area DA on the mother substrate MSUB. Each of the display layers DP may include a light emitting element layer (e.g., the light emitting element layer LDL of FIG. 3). An encapsulation layer (e.g., the encapsulation layer TFE of FIG. 3), a color filter layer (e.g., the color filter layer CFL of FIG. 3), a lens layer (e.g., the lens layer LL of FIG. 3), and a filling layer (e.g., the filling layer OL of FIG. 3) may be formed sequentially on the light emitting element layer.

The first sealing members SL1 may be formed on the mother substrate MSUB in a non-display area NDA. The first sealing members SL1 may cover side surfaces of the display layer DP.

The pad portions PP may be formed on the mother substrate MSUB in the non-display area NDA. For example, the non-display area NDA may be adjacent to (e.g., surround) the display area DA.

In FIG. 6, nine display layers DP and nine pad portions PP may be formed on the mother substrate MSUB, but the disclosure is not limited thereto. For example, less than nine display layers DP and less than nine pad portions PP may be formed on the mother substrate MSUB. For another example, more than nine display layers DP and more than nine pad portions PP may be formed on the mother substrate MSUB.

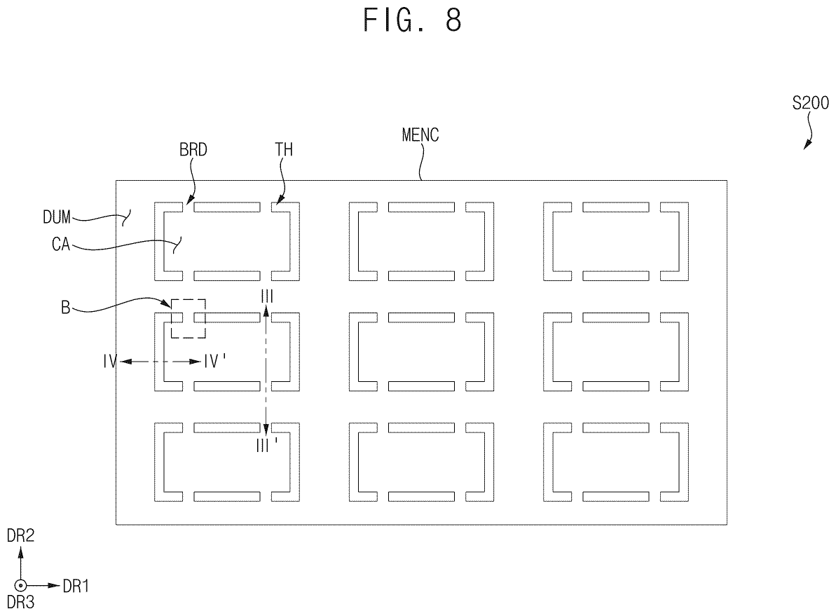

Referring to FIGS. 8 to 11, a preliminary encapsulation substrate MENC may be processed, and a through portion TH may be formed in a dummy area DUM. Thus, a bridge BRD connecting a cell area CA and the dummy area DUM may be formed (S200).

The preliminary encapsulation substrate MENC may include a transparent material. For example, the preliminary encapsulation substrate MENC may include glass or plastic (or synthetic resin). The preliminary encapsulation substrate MENC may have a rectangular planar shape. However, the planar shape of the preliminary encapsulation substrate MENC is not limited thereto, and the preliminary encapsulation substrate MENC may have various planar shapes such as a circular shape, an ellipse shape, a polygonal shape, or the like.

The preliminary encapsulation substrate MENC may include the cell area CA and the dummy area DUM. In case that the mother substrate MSUB and the preliminary encapsulation substrate MENC are bonded to each other, the cell area CA may overlap the display area DA and the non-display area NDA. For example, the mother substrate MSUB and the preliminary encapsulation substrate MENC may be bonded to each other, and the cell area CA may entirely overlap the display area DA and may partially overlap the non-display area NDA. The dummy area DUM may be adjacent to (e.g., surround) the cell area CA. The dummy area DUM of the preliminary encapsulation substrate MENC may be separated from the mother substrate MSUB after the cutting of the bridge BRD (S600). Detailed description of the cutting of the bridge BRD (S600) is provided below. For example, after the cutting of the bridge BRD (S600), the cell area CA of the preliminary encapsulation substrate MENC may be positioned on the mother substrate MSUB. For example, only the cell area CA of the preliminary encapsulation substrate MENC may be positioned (or may remain) on the mother substrate MSUB after the cutting of the bridge BRD (S600).

The preliminary encapsulation substrate MENC may be processed, and the through portion TH may be formed in the dummy area DUM to form the bridge BRD connecting the cell area CA and the dummy area DUM. For example, the through portion TH may be adjacent to (e.g., surround) the cell area CA, excluding an area where the bridge BRD is positioned. For example, the through portion TH may surround the cell area CA and may not be formed in the area where the bridge BRD is positioned.

In an embodiment, the preliminary encapsulation substrate MENC may be processed using a laser LAS. For example, the preliminary encapsulation substrate MENC may be processed using laser-induced deep etching (LIDE) technology. However, the disclosure is not limited thereto, and the preliminary encapsulation substrate MENC may be processed using various physical processing methods.

The bridge BRD may connect the cell area CA and the dummy area DUM. The bridge BRD may be positioned adjacent to the through portion TH. In FIG. 7, four bridges BRD may be formed in each cell area CA, but the disclosure is not limited thereto.

In an embodiment, the bridge BRD may extend in the second direction DR2. However, the disclosure is not limited thereto. In another embodiment, the bridge BRD may extend in the first direction DR1. In still another embodiment, the bridge BRD may extend in the first direction DR1 and the second direction DR2.

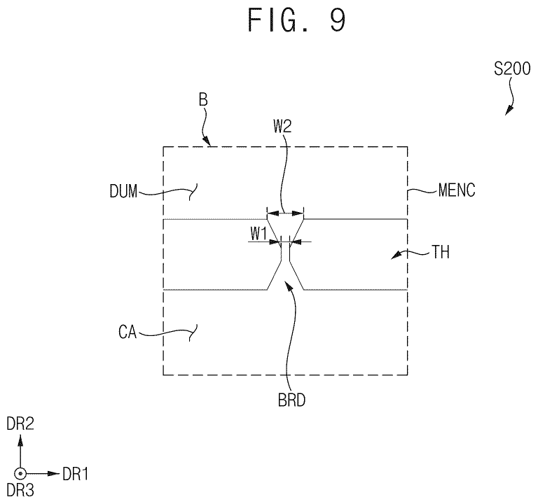

In an embodiment, as illustrated in FIG. 9, a width W1 of a central portion of the bridge BRD may be smaller than a width W2 of each end of the bridge BRD. Accordingly, the bridge BRD may be cut with a relatively small impact in the cutting of the bridge BRD (S600). Detailed description of the cutting of the bridge BRD (S600) is described below,. For example, the width of the bridge BRD may be in a range of about 30 micrometers to about 100 micrometers.

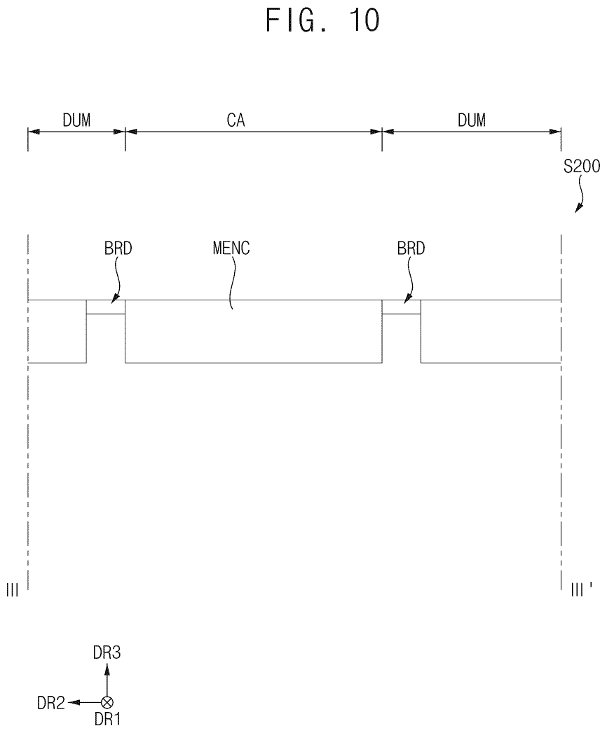

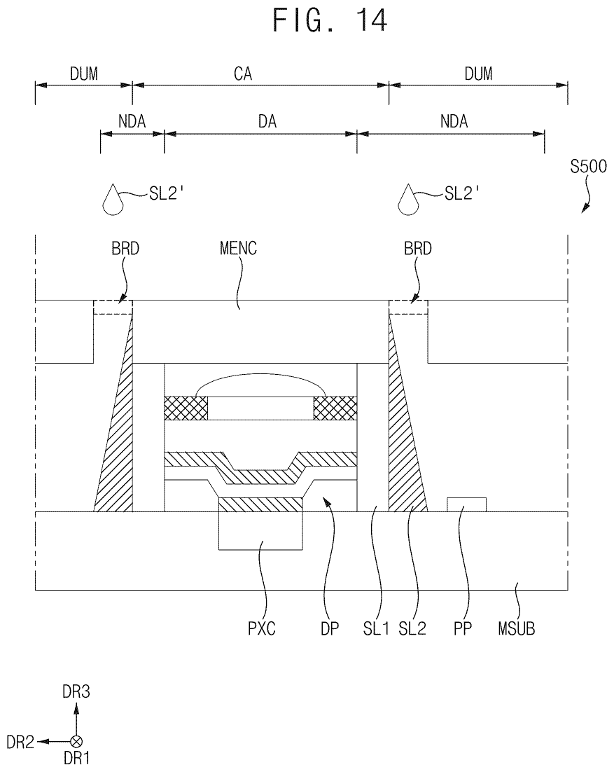

In an embodiment, as illustrated in FIG. 10, a thickness of the bridge BRD may be smaller than a thickness of the preliminary encapsulation substrate MENC. Accordingly, the second sealing member SL2 may extend to an upper portion of a side surface of the preliminary encapsulation substrate MENC adjacent to the through portion TH in applying (e.g., coating) a second sealing member SL2 (S500). A detailed description thereof is described below with reference to FIG. 14.

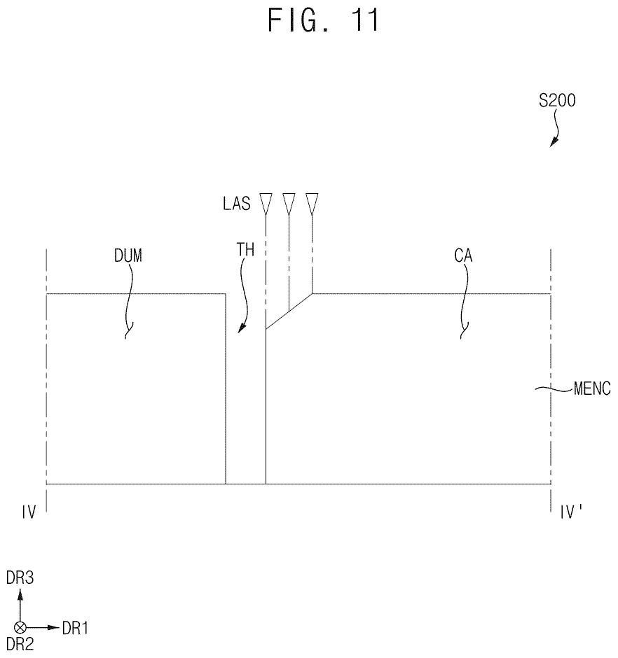

In an embodiment, as illustrated in FIG. 11, the forming of the through portion TH in the dummy area DUM (S200) may include processing a side surface of the preliminary encapsulation substrate MENC, which overlaps the cell area CA and is exposed by the through hole TH, to have a chamfered shape. For example, the side surface of the preliminary encapsulation substrate MENC exposed by the through portion TH may have a chamfered shape except for an area where the bridge BRD is positioned. Accordingly, concentration of stress on the side surface of the preliminary encapsulation substrate MENC exposed by the through portion TH may be prevented. For example, resistance against impact of the side surface of the preliminary encapsulation substrate MENC exposed by the through portion TH may be increased.

The laser LAS may be irradiated to an upper surface of the preliminary encapsulation substrate MENC and the depth of the laser LAS may be adjusted. Thus, the chamfered shape may be formed on the side surface of the preliminary encapsulation substrate MENC. For example, the depth of the laser LAS irradiated to an upper surface of the preliminary encapsulation substrate MENC may increase as the upper surface of the preliminary encapsulation substrate MENC approaches the through portion TH. Accordingly, the side surface of the preliminary encapsulation substrate MENC adjacent to the through portion TH may have a chamfered shape. In other embodiments, the laser LAS may also be irradiated to a lower surface of the preliminary encapsulation substrate MENC. The depth of the laser LAS irradiated to the lower surface of the preliminary encapsulation substrate MENC may increase as the lower surface of the preliminary encapsulation substrate MENC approaches the through portion TH.

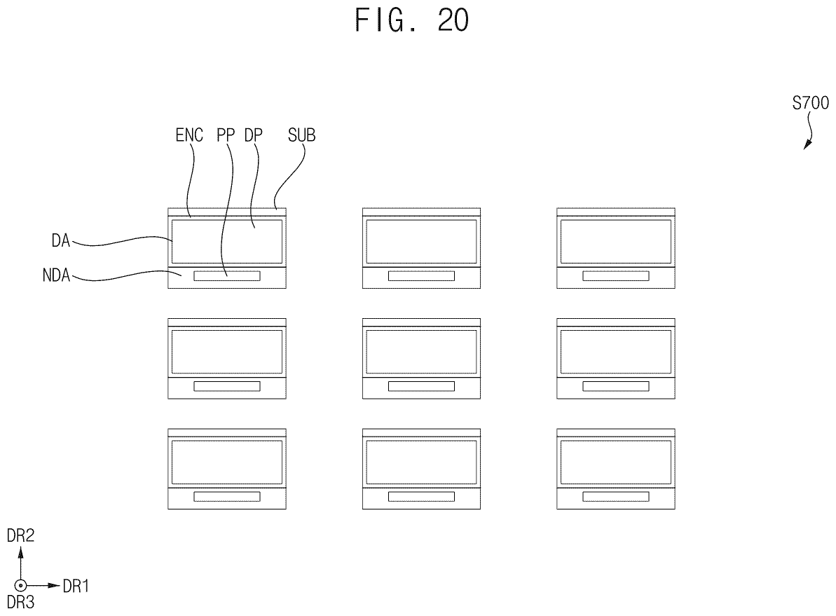

In an embodiment, between the forming of the through portion TH in the dummy area DUM (S200) and the cutting of the bridge BRD (S600), the preliminary encapsulation substrate MENC may be strengthened (S300). For example, the preliminary encapsulation substrate MENC may be strengthened using an ion exchange process. The ion exchange process may be performed by treating a material including alkaline ions on the preliminary encapsulation substrate MENC. For example, the material including the alkali ions may include potassium nitrate (KNO₃), sodium nitrate (NaNO₃), etc. In the manufacturing method MM according to an embodiment of the disclosure, since the bridge BRD is cut to separate the dummy area DUM of the preliminary encapsulation substrate MENC from the mother substrate MSUB, a strengthening process may be performed in the preliminary encapsulation substrate MENC. For example, the dummy area DUM of the preliminary encapsulation substrate MENC may be separated from the mother substrate MSUB without using a physical processing method such as using a diamond wheel or dicing saw. Thus, the strengthening process may be performed in the preliminary encapsulation substrate MENC. Accordingly, compared to a case where the strengthening process is performed on each of encapsulation substrates (e.g., an encapsulation substrate ENC of FIG. 20), the strengthening process may be relatively simplified.

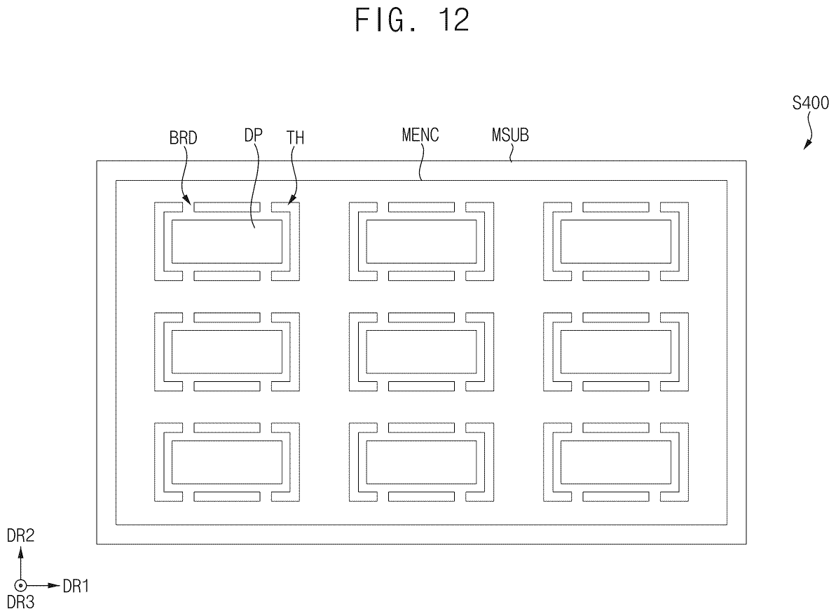

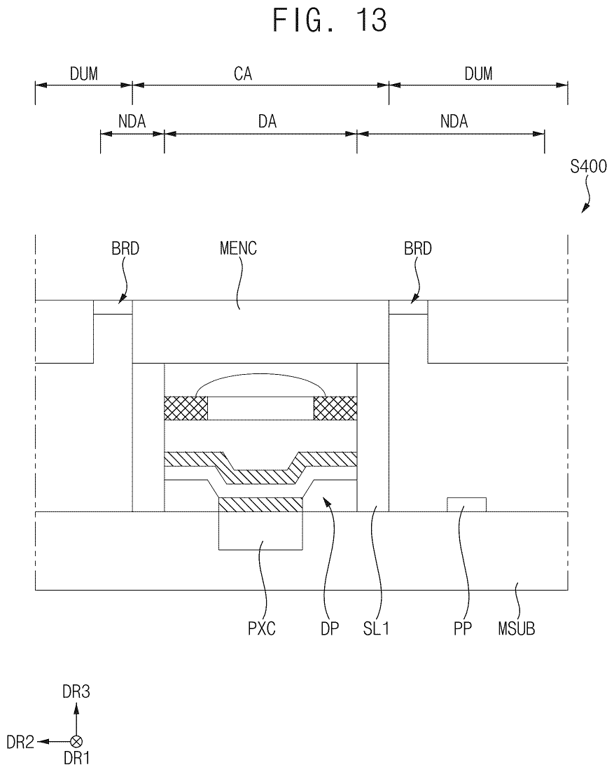

Referring to FIGS. 12 and 13, the mother substrate MSUB and the preliminary encapsulation substrate MENC may be bonded to each other (S400).

The mother substrate MSUB and the preliminary encapsulation substrate MENC may be bonded to each other, and the cell area CA of the preliminary encapsulation substrate MENC may overlap the display area DA and the non-display area NDA. For example, the cell area CA of the preliminary encapsulation substrate MENC may entirely overlap the display area DA and partially overlap the non-display area NDA. The through portion TH may be adjacent to (e.g., surround) the display area DA in a plan view. For example, the cell area CA of the preliminary encapsulation substrate MENC may overlap (e.g., entirely overlap) the display layer DP and the first sealing member SL1. The bridge BRD may be spaced apart from the display layer DP in a plan view. The bridge BRD may be spaced apart from the pad portion PP in a plan view.

Referring to FIG. 14, the second sealing member SL2 may be applied through the through portion TH (e.g., refer to FIG. 12) (S500). For example, a droplet SL2′ for forming the second sealing member SL2 may be dropped on the preliminary encapsulation substrate MENC and pass through the through portion TH. Thus, the second sealing member SL2 may be formed. The second sealing member SL2 may extend from an upper surface of the mother substrate MSUB to the side surface of the preliminary encapsulation substrate MENC exposed by the through portion TH.

The second sealing member SL2 may be applied on the mother substrate MSUB through the through portion TH. In case that the second sealing member SL2 is applied on the mother substrate MSUB through the through portion TH, the second sealing member SL2 may extend from the upper surface of the mother substrate MSUB to the side surface of the preliminary encapsulation substrate MENC exposed by the through portion TH. Accordingly, the second sealing member SL2 may cover a side surface of the first sealing member SL1. The second sealing member SL2 may have a triangular cross-sectional shape, but the disclosure is not limited thereto.

In an embodiment, the thickness of the bridge BRD may be smaller than the thickness of the preliminary encapsulation substrate MENC. The second sealing member SL2 may extend to an upper portion of the side surface of the preliminary encapsulation substrate MENC exposed by the through portion TH.

Accordingly, the second sealing member SL2 may support the preliminary encapsulation substrate MENC in the cell area CA. In case that the second sealing member SL2 supports the preliminary encapsulation substrate MENC in the cell area CA, misalignment of the preliminary encapsulation substrate MENC in the cell area CA may be prevented in the cutting of the bridge BRD by applying an impact (S600). Detailed description of the cutting of the bridge BRD (S600) is provided below.

In other embodiments, the applying of the second sealing member SL2 through the through portion TH (S500) may be omitted. After the bonding of the mother substrate MSUB and the preliminary encapsulation substrate MENC (S400), the cutting of the bridge BRD (S600) may be continuously performed.

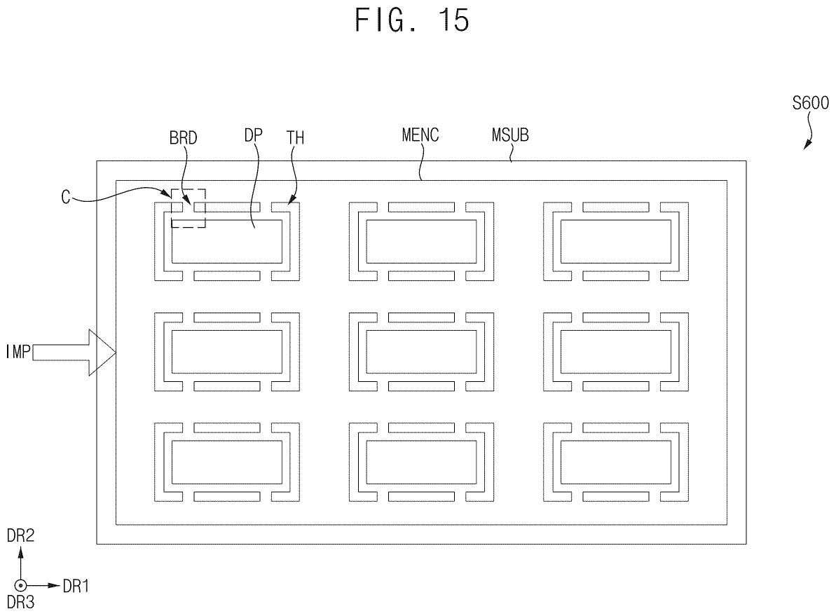

Referring to FIGS. 15 to 17, the bridge BRD is cut and the dummy area DUM of the preliminary encapsulation substrate MENC may be separated from the mother substrate MSUB (S600).

In an embodiment, an impact IMP may be applied to an outer side surface of the preliminary encapsulation substrate MENC, and the bridge BRD may be cut. However, the disclosure is not limited thereto, and the bridge BRD may be cut by irradiating a laser to both ends of the bridge BRD.

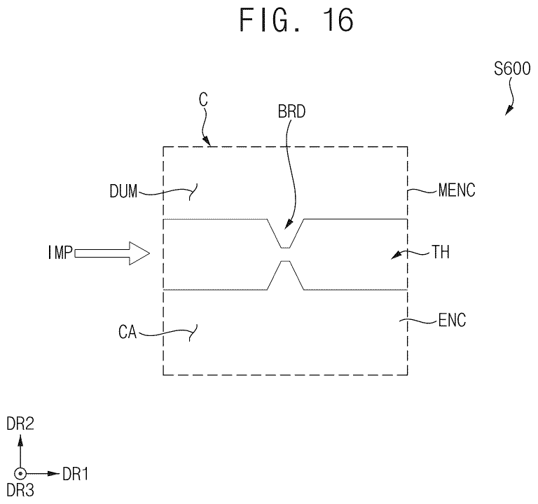

In an embodiment, the impact IMP may be applied in a direction perpendicular to a direction in which the bridge BRD extends. As illustrated in FIG. 16, in case that the bridge BRD extends in the second direction DR2, the impact IMP may be applied in the first direction DR1. However, the disclosure is not limited thereto. In another embodiment, the impact IMP may be applied in a diagonal direction between the second direction DR2 in which the bridge BRD extends and the first direction DR1.

In case that the impact IMP is applied to the outer side surface of the preliminary encapsulation substrate MENC, stress may be concentrated in a portion where the width of the bridge BRD is smallest. Accordingly, the bridge BRD may be cut at the portion where the width of the bridge BRD is smallest.

After the cutting of the bridge BRD (S600), the dummy area DUM of the preliminary encapsulation substrate MENC may be separated from the mother substrate MSUB. For example, after the cutting of the bridge BRD (S600), the cell area CA of the preliminary encapsulation substrate MENC may be positioned on the mother substrate MSUB. For example, only the cell area CA of the preliminary encapsulation substrate MENC may be positioned (or may remain) on the mother substrate MSUB. Accordingly, an encapsulation substrate ENC may be formed on the display layer DP and the first sealing member SL1.

In the manufacturing method MM according to an embodiment of the disclosure, the impact IMP may be applied to the preliminary encapsulation substrate MENC, and the dummy area DUM of the preliminary encapsulation substrate MENC may be separated from the mother substrate MSUB. Thus, the physical processing method using a diamond wheel or a dicing saw may not be utilized. Accordingly, the problem of fine-sized fragments of the preliminary encapsulation substrate MENC, which may be generated during the physical processing method, remaining on the encapsulation substrate ENC may be suppressed.

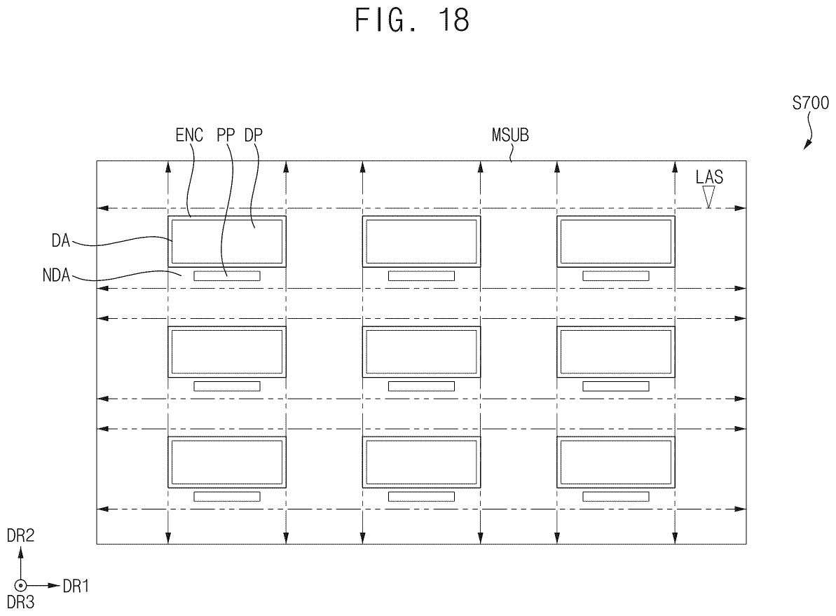

Referring to FIGS. 18 to 20, the mother substrate MSUB may be cut (S700).

The mother substrate MSUB may be cut to form substrates SUB. The cutting of the mother substrate MSUB (S700) may be performed by irradiating a laser LAS to the mother substrate MSUB. For example, the mother substrate MSUB may be cut along sides adjacent to the display layer DP and the pad portion PP, respectively, and other sides adjacent to the display layer DP and the pad portion PP, respectively. Accordingly, the display layer DP may be disposed in the display area DA on the substrate SUB, and the pad portion PP may be disposed in the non-display area NDA on the substrate SUB.

A polarization layer (e.g., the polarization layer POL of FIG. 3) may be formed on the encapsulation substrate ENC. The polarization layer may overlap (e.g., entirely overlap) the encapsulation substrate ENC. In other embodiments, the polarization layer may be omitted.

Accordingly, a display device including the substrate SUB, the display layer DP, the pad portion PP, and the encapsulation substrate ENC may be formed.

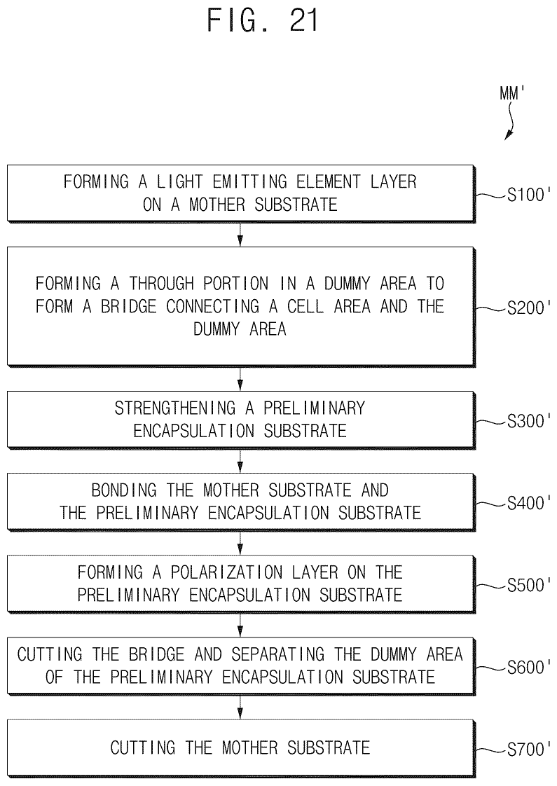

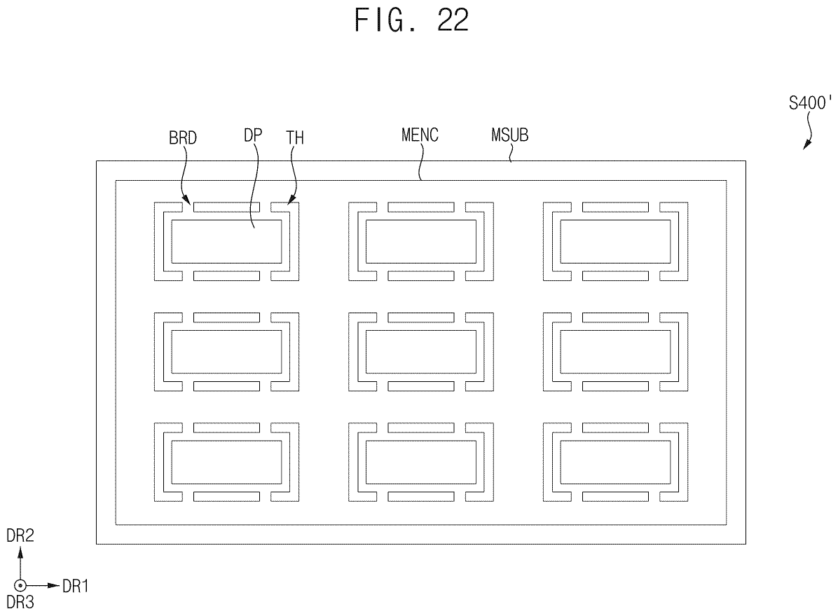

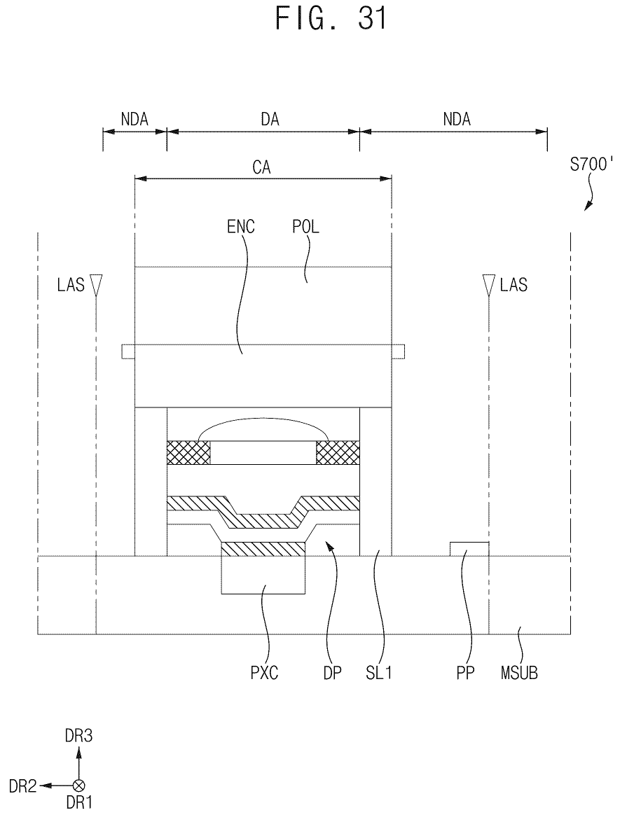

FIG. 21 is a schematic flowchart of a method of manufacturing a display device according to another embodiment of the disclosure. FIGS. 22 to 32 are schematic views illustrating the method of manufacturing the display device of FIG. 21.

Referring to FIG. 21, a method MM′ of manufacturing a display device according to another embodiment of the disclosure may include forming a light emitting element layer on a mother substrate (S100′), forming a through portion in a dummy area to form a bridge connecting a cell area and the dummy area (e.g., processing a preliminary encapsulation substrate and forming the through portion in the dummy area to form the bridge connecting the cell area and the dummy area) (S200′), strengthening the preliminary encapsulation substrate (S300′), bonding the mother substrate and the preliminary encapsulation substrate (S400′), forming a polarization layer on the preliminary encapsulation substrate (S500′), cutting the bridge and separating the dummy area of the preliminary encapsulation substrate (S600′), and cutting the mother substrate (S700′). For example, the method MM′ of manufacturing the display device may include the forming of the light element layer on the mother substrate (S100′), the forming of the bridge connecting the cell area and the dummy area (S200′), the strengthening of the preliminary encapsulation substrate (S300′), the bonding of the mother substrate and the preliminary encapsulation substrate (S400′), the forming of the polarization layer on the preliminary encapsulation substrate (S500′), the separating of the dummy area of the preliminary encapsulation substrate (S600′), and the cutting of the mother substrate (S700′). The forming of the bridge connecting the cell area and the dummy area (S200′) may include the processing of the preliminary encapsulation substrate and the forming of the through portion in the dummy area. The separating of the dummy area of the preliminary encapsulation substrate (S600′) may include the cutting of the bridge.

The forming of the light emitting element layer on the mother substrate (S100′) may be substantially the same as the forming of the light emitting element layer on the mother substrate (S100) described with reference to FIGS. 7 and 8.

The processing of the preliminary encapsulation substrate and the forming of the through portion in the dummy area to form the bridge connecting the cell area and the dummy area (S200′) may be substantially the same as the processing of the preliminary encapsulation substrate and the forming of the through portion in the dummy area to form the bridge connecting the cell area and the dummy area (S200) described with reference to FIGS. 9 to 11.

The strengthening of the preliminary encapsulation substrate (S300′) may be substantially the same as the strengthening of the preliminary encapsulation substrate (S300).

The bonding of the mother substrate and the preliminary encapsulation substrate (S400′) may be substantially the same as the bonding of the mother substrate and the preliminary encapsulation substrate (S400) described with reference to FIGS. 12 and 13.

The cutting of the mother substrate (S700′) may be substantially the same as the cutting of the mother substrate (S700) described with reference to FIGS. 18 to 20. Therefore, hereinafter, detailed description of the method MM of manufacturing the display device described with reference to FIGS. 6 to 20 is omitted or simplified.

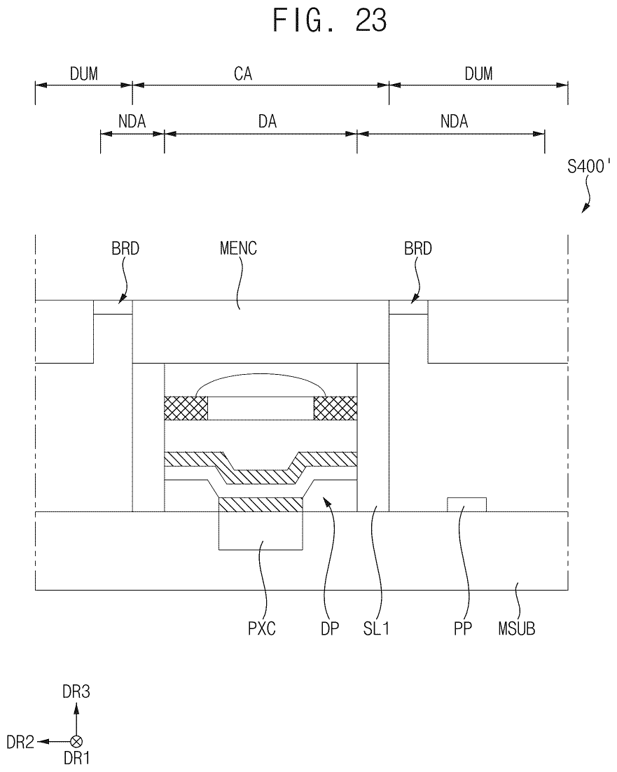

Referring to FIGS. 22 and 23, the mother substrate MSUB and the preliminary encapsulation substrate MENC may be bonded to each other (S400′).

In case that the mother substrate MSUB and the preliminary encapsulation substrate MENC are bonded to each other, the cell area CA of the preliminary encapsulation substrate MENC may overlap the display area DA and the non-display area NDA. For example, the mother substrate MSUB and the preliminary encapsulation substrate MENC may be bonded to each other, and the cell area CA of the preliminary encapsulation substrate MENC may entirely overlap the display area DA and partially overlap the non-display area NDA. The through portion TH may be adjacent to (e.g., surround) the display area DA in a plan view. For example, the cell area CA of the preliminary encapsulation substrate MENC may overlap (e.g., entirely overlap) the display layer DP and the first sealing member SL1. The bridge BRD may be spaced apart from the display layer DP in a plan view. The bridge BRD may be spaced apart from the pad portion PP in a plan view. For example, the bridge BRD may be spaced apart from the display layer DP and the pad portion PP in a plan view.

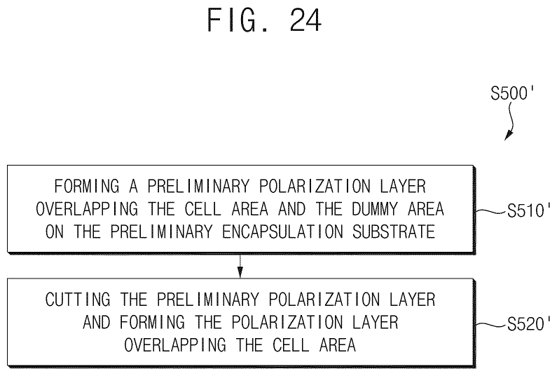

Referring to FIGS. 24 to 27, a polarization layer POL may be formed on the preliminary encapsulation substrate MENC (S500′). The forming of the polarization layer POL on the preliminary encapsulation substrate MENC (S500′) may include forming a preliminary polarization layer PPOL overlapping the cell area CA and the dummy area DUM on the preliminary encapsulation substrate MENC (S510′), and cutting the preliminary polarization layer PPOL and forming the polarization layer POL overlapping the cell area CA (S520′).

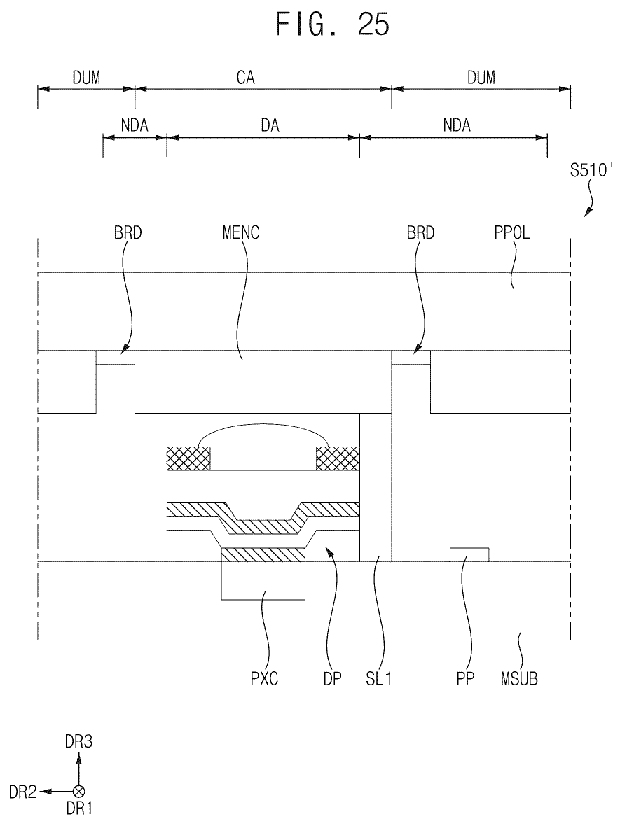

As illustrated in FIG. 25, the preliminary polarization layer PPOL overlapping the cell area CA and the dummy area DUM may be formed on the preliminary encapsulation substrate MENC (S510′). Accordingly, the preliminary polarization layer PPOL may overlap the bridge BRD.

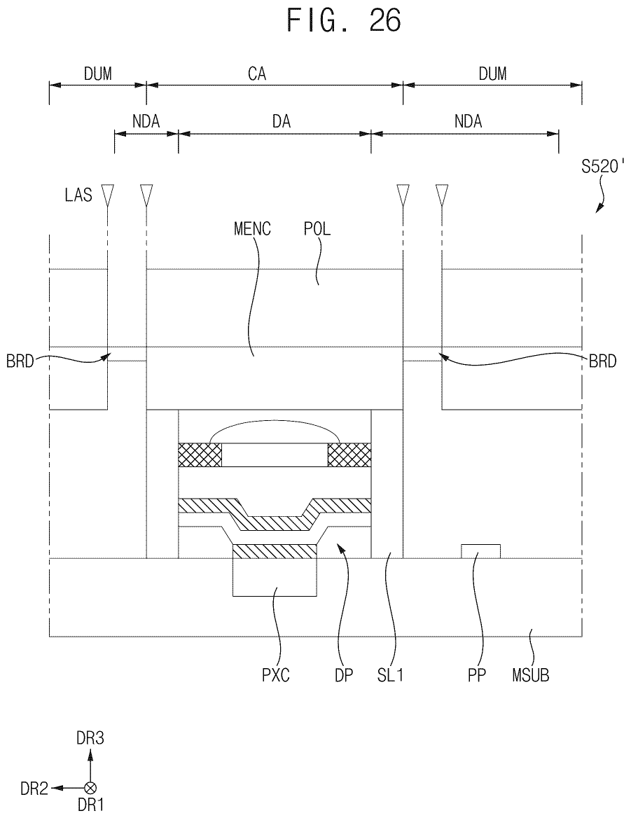

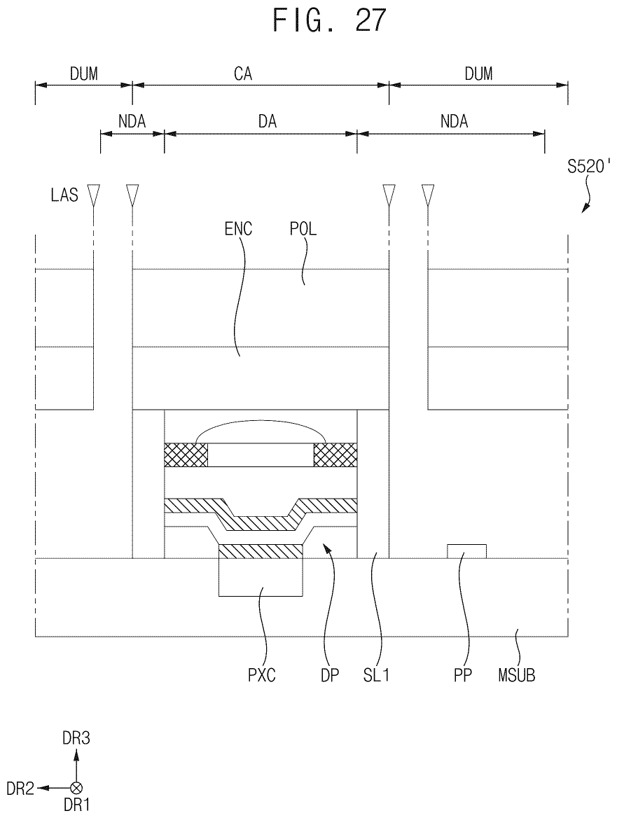

As illustrated in FIGS. 26 and 27, the preliminary polarization layer PPOL may be cut, and the polarization layer POL overlapping the cell area CA may be formed (S520′). In an embodiment, a laser LAS may be irradiated on ends of the bridge BRD, and the preliminary polarization layer PPOL may be cut. For example, the irradiation of the laser LAS may overlap both ends of the bridge BRD.

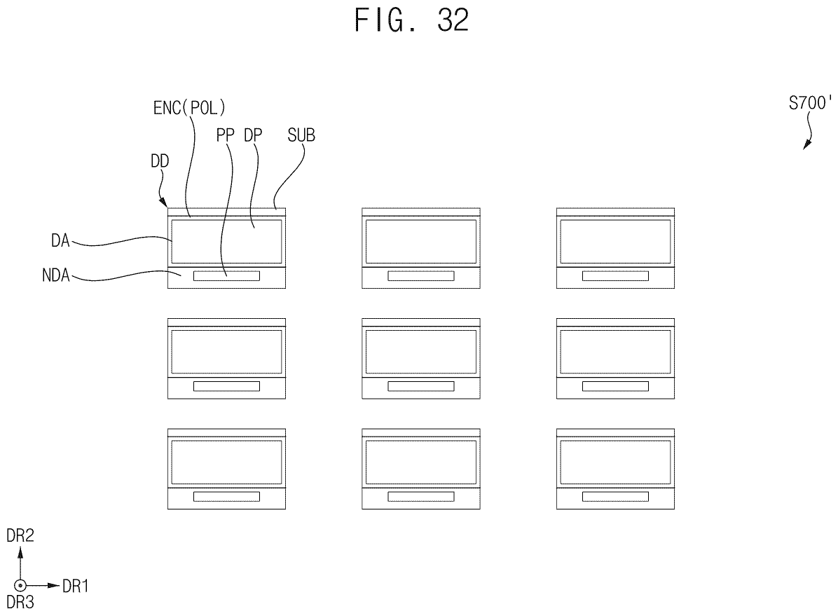

The polarization layer POL may be formed before the cutting of the mother substrate MSUB. Accordingly, the polarization layer POL may be formed on the preliminary encapsulation substrate MENC. For example, the polarization layer POL and the preliminary encapsulation substrate MENC may be integral with each other to form a part. For example, compared to a case of forming the polarization layer POL on each of encapsulation substrates (e.g., an encapsulation substrate ENC of FIG. 32), the forming of the polarization layer POL may be relatively simplified.

In an embodiment, as illustrated in FIG. 26, the bridge BRD may not be cut by the laser LAS, and the preliminary polarization layer PPOL (e.g., refer to FIG. 25) may be cut by the laser LAS. For example, the laser LAS may be irradiated to the preliminary polarization layer PPOL, and the depth of the laser LAS may be adjusted. Thus, the preliminary polarization layer PPOL may be cut without cutting the bridge BRD. For example, the cutting of the preliminary polarization layer PPOL (S520′) and the cutting of the bridge BRD (S600′) may be performed separately. For example, the cutting of the preliminary polarization layer PPOL (S520′) may be performed before the cutting of the bridge BRD (S600′).

In another embodiment, as illustrated in FIG. 27, each of the bridge BRD (e.g., refer to FIG. 26) and the preliminary polarization layer PPOL (e.g., refer to FIG. 25) may be cut by the laser LAS. For example, in case that the laser LAS is irradiated to both ends of the bridge

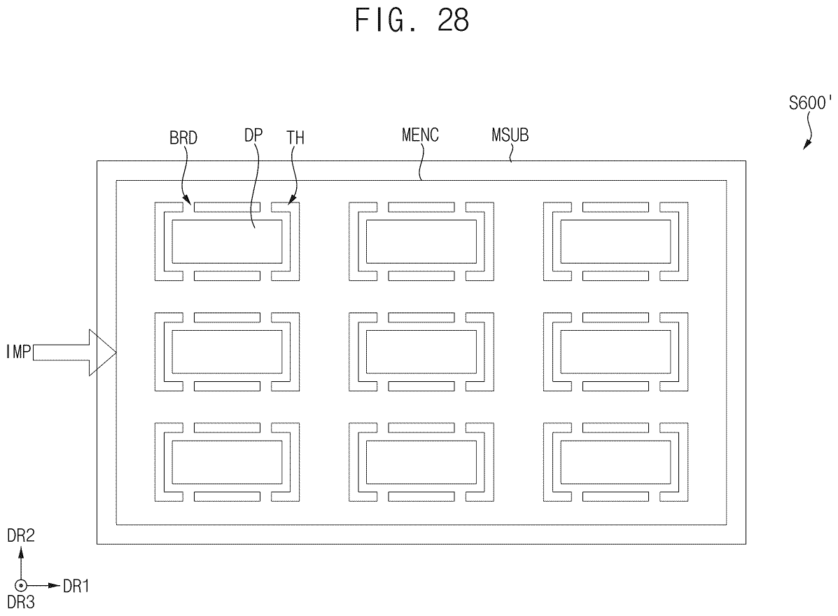

BRD, the bridge BRD and the preliminary polarization layer PPOL may be cut by the irradiation of the laser LAS. For example, the cutting of the preliminary polarization layer PPOL (S520′) and the cutting of the bridge BRD (S600′) may be performed simultaneously. Thus, the bridge BRD may be cut without application of an impact (e.g., an impact IMP of FIG. 28).

In other embodiments, the forming of the polarization layer POL on the preliminary encapsulation substrate MENC (S500′) may be performed before the bonding of the mother substrate MSUB and the preliminary encapsulation substrate MENC (S400′).

Before the bonding of the mother substrate MSUB and the preliminary encapsulation substrate MENC, the presence of foreign matter between the preliminary encapsulation substrate MENC and the polarization layer POL may be checked.

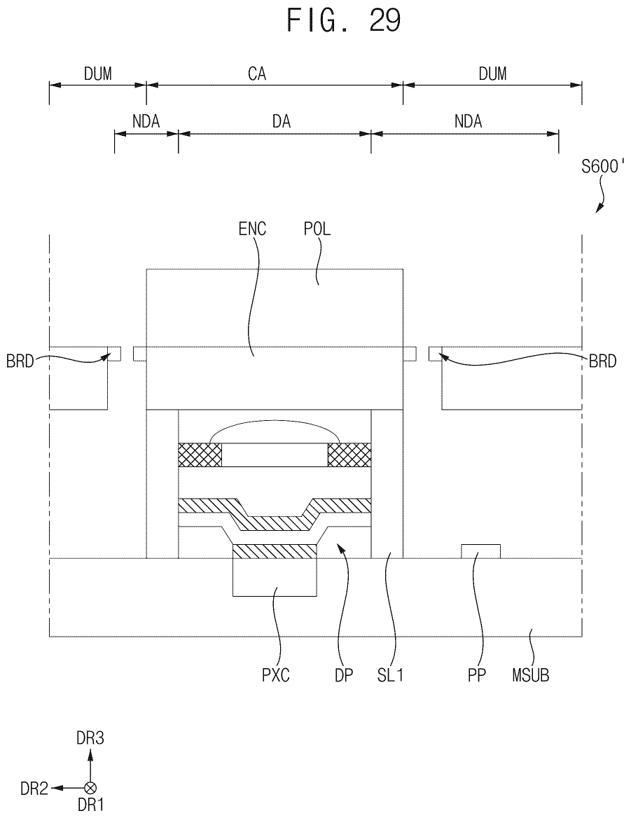

Referring to FIGS. 28 and 29, the bridge BRD may be cut and the dummy area DUM of the preliminary encapsulation substrate MENC may be separated from the mother substrate MSUB (S600′).

An impact IMP may be applied to the outer side surface of the preliminary encapsulation substrate MENC, and the bridge BRD may be cut. In other embodiments, as illustrated in FIG. 27, the bridge BRD may be cut by irradiating a laser to both ends of the bridge BRD.

In an embodiment, the impact IMP may be applied in a direction perpendicular to a direction in which the bridge BRD extends. In another embodiment, the impact IMP may be applied in a diagonal direction between the direction in which the bridge BRD extends and the direction perpendicular to the direction in which the bridge BRD extends.

In case that the impact IMP is applied to the outer side surface of the preliminary encapsulation substrate MENC, stress may be concentrated in a portion where the width of the bridge BRD is smallest. Accordingly, the bridge BRD may be cut at the portion where the width of the bridge BRD is smallest.

After the cutting of the bridge BRD, the dummy area DUM of the preliminary encapsulation substrate MENC may be separated from the mother substrate MSUB. For example, after the cutting of the bridge BRD, the cell area CA of the preliminary encapsulation substrate MENC may be positioned on the mother substrate MSUB. For example, only the cell area CA of the preliminary encapsulation substrate MENC may be positioned (or may remain) on the mother substrate MSUB.

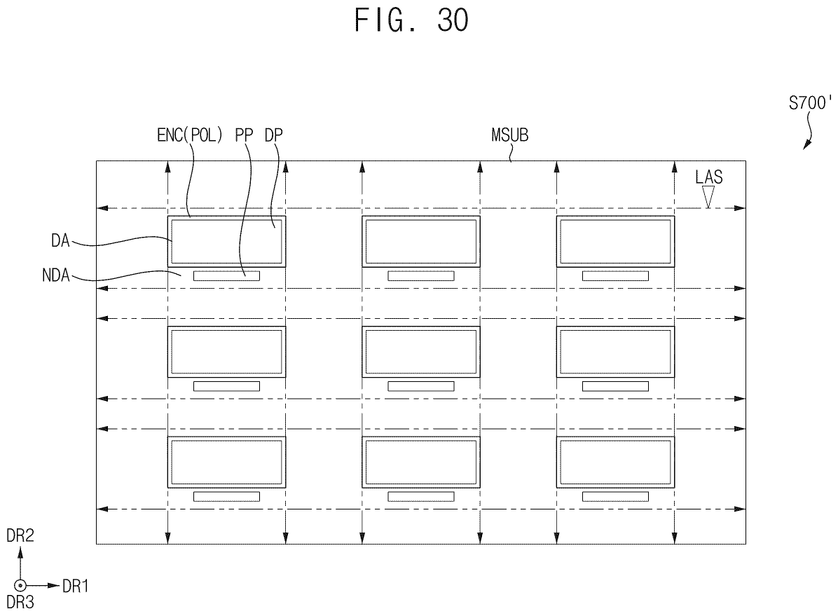

Referring to FIGS. 30 to 32, the mother substrate MSUB may be cut (S700′).

The mother substrate MSUB may be cut to form substrates SUB. A laser LAS may be irradiated to the mother substrate MSUB, and the mother substrate MSUB may be cut (S700′) may be performed by irradiating a laser LAS. For example, the mother substrate MSUB may be cut along sides adjacent to the display layer DP and the pad portion PP, respectively, and other sides adjacent to the display layer DP and the pad portion PP, respectively. For example, the laser LAS may be irradiated to an upper side, a left side, and a right side of the display layer DP and a lower side of the pad portion PP. Accordingly, the display layer DP may be disposed in the display area DA on the substrate SUB, and the pad portion PP may be disposed in the non-display area NDA on the substrate SUB.

Accordingly, the display device DD including the substrate SUB, the display layer DP, the pad portion PP, the encapsulation substrate ENC, and the polarization layer POL may be formed.

The disclosure may be applied to various display devices. For example, the disclosure may be applicable to various display devices such as display devices for vehicles, ships, aircrafts, portable communication devices, display devices for exhibition or information transmission, medical display devices, and the like.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
forming a light emitting element layer on a mother substrate;
forming a through portion in a dummy area of a preliminary encapsulation substrate to form at least one bridge connecting a cell area of the preliminary encapsulation substrate and the dummy area adjacent to the cell area;
bonding the mother substrate and the preliminary encapsulation substrate;
applying a sealing member through the through portion, the sealing member extending from an upper surface of the mother substrate to a side surface of the preliminary encapsulation substrate which is exposed by the through portion; and
cutting the at least one bridge and separating the dummy area of the preliminary encapsulation substrate.

2. The method of claim 1, wherein the cutting of the at least one bridge includes applying an impact to an outer side surface of the preliminary encapsulation substrate.

3. The method of claim 2, wherein the applying of the impact to the outer side surface of the preliminary encapsulation substrate includes applying the impact in a second direction perpendicular to a first direction in which the at least one bridge extends.

4. The method of claim 2, wherein the applying of the impact to the outer side surface of the preliminary encapsulation substrate includes applying the impact in a diagonal direction between a first direction in which the at least one bridge extends and a second direction perpendicular to the first direction.

5. The method of claim 1, wherein a width of a central portion of the at least one bridge is smaller than a width of each end of the at least one bridge.

6. The method of claim 1, wherein a thickness of the at least one bridge is smaller than a thickness of the preliminary encapsulation substrate.

7. The method of claim 1, wherein
the forming of the through portion in the dummy area includes processing the side surface of the preliminary encapsulation substrate to have a chamfered shape, and
the side surface of the preliminary encapsulation substrate overlaps the cell area and is exposed by the through portion.

8. The method of claim 1, further comprising:
strengthening the preliminary encapsulation substrate through an ion exchange process between the forming of the through portion in the dummy area and the cutting of the at least one bridge,

9. The method of claim 1, wherein the mother substrate is formed of a silicon wafer.

10. A method of manufacturing a display device, the method comprising:
forming a light emitting element layer on a mother substrate;
forming a through portion in a dummy area of a preliminary encapsulation substrate to form at least one bridge connecting a cell area of the preliminary encapsulation substrate and the dummy area adjacent to the cell area;
forming a polarization layer on the preliminary encapsulation substrate;
bonding the mother substrate and the preliminary encapsulation substrate; and
cutting the at least one bridge and separating the dummy area of the preliminary encapsulation substrate.

11. The method of claim 10, wherein the forming of the polarization layer includes:
forming a preliminary polarization layer overlapping the cell area and the dummy area on the preliminary encapsulation substrate; and
cutting the preliminary polarization layer and forming the polarization layer overlapping the cell area.

12. The method of claim 11, wherein
the cutting of the preliminary polarization layer comprises irradiating a laser to the preliminary polarization layer, and
the irradiation of the laser overlaps both ends of the at least one bridge.

13. The method of claim 12, wherein the cutting of the preliminary polarization layer comprises simultaneously cutting the preliminary polarization layer and the at least one bridge using the laser.

14. The method of claim 11, wherein the cutting of the preliminary polarization layer is performed before the cutting of the at least one bridge.

15. The method of claim 14, wherein the cutting of the at least one bridge includes applying an impact to an outer side surface of the preliminary encapsulation substrate.

16. The method of claim 15, wherein the applying of the impact to the outer side surface of the preliminary encapsulation substrate includes applying the impact in a second direction perpendicular to a first direction in which the at least one bridge extends.

17. The method of claim 15, the applying of the impact to the outer side surface of the preliminary encapsulation substrate includes applying the impact in a diagonal direction between a first direction in which the at least one bridge extends and a second direction perpendicular to the first direction.

18. The method of claim 10, wherein a width of a central portion of the at least one bridge is smaller than a width of each end of the at least one bridge.

19. The method of claim 10, wherein
the forming of the through portion in the dummy area includes processing a side surface of the preliminary encapsulation substrate to have a chamfered shape, and
the side surface of the preliminary encapsulation substrate overlaps the cell area and is exposed by the through portion.

20. The method of claim 10, further comprising:
strengthening the preliminary encapsulation substrate through an ion exchange process between the forming of the through portion in the dummy area and the cutting of the at least one bridge.
